(19) United States
(12) Patent Application Publication
(10) Pub. No.: US 2014/0065819 A1
(43) Pub. Date: Mar. 6, 2014

(54) Methods and Systems for Low Resistance Contact Formation

(71) Applicant: INTERMOLECULAR, INC., San Jose, CA (US)

(72) Inventors: Khaled Ahmed, Anaheim, CA (US); Tony P. Chiang, Campbell, CA (US)

(73) Assignee: INTERMOLECULAR, INC., San Jose, CA (US)

(21) Appl. No.: 13/672,621

(22) Filed: Nov. 8, 2012

Related U.S. Application Data
(60) Provisional application No. 61/696,287, filed on Sep. 3, 2012.

(51) Int. Cl. H01L 21/3205

(52) U.S. Cl. 438/664; 257/E21.296

(57) ABSTRACT

Methods for improving contact resistance, for example, to a semiconductor region such as a source or a drain region, are disclosed. The methods can include depositing a layer on a substrate, wherein the layer can include a first element to form a silicide with the substrate and a second element to lower a contact resistance between the silicide and the substrate. The second element can include a dopant, which can enhance trap assisted tunneling or lower the Schottky barrier height between the silicide layer and the substrate.

### CROSS-REFERENCE TO RELATED APPLICATIONS

This application claims priority to U.S. Provisional Application No. 61/696,287, filed Sep. 3, 2012, which is incorporated by reference herein in its entirety.

### TECHNICAL FIELD

The present invention relates to methods to form a semiconductor device, and more particularly to methods to improve contact resistance of the semiconductor device.

### BACKGROUND

Performances of semiconductor devices have been improved by proportional shrinkage of device-feature lengths while retaining proper operations of the transistors. For example, low resistance contact layers can be formed on source/drain regions of transistors to improve performance, such as lowering the parasitic resistance. An example of a low resistance contact layer is the silicide layer, formed by reacting a metal layer with the silicon substrate.

A Schottky junction is formed between the silicide layer and the silicon substrate, e.g., the source or drain regions of the transistor. However, the interface resistance between the silicide layer and the silicon substrate does not scale down with the shrinkage of the transistor devices. Thus reducing contact resistance can be an important issue in the improvement of the performance of future devices.

A prior approach to reduce contact resistance of a source or drain contact is to implant a dopant, such as tellurium, before the formation of the silicide layer. Tellurium can segregate to the interface of the silicide layer and the silicon source or drain region, forming a dopant segregated layer with a higher level of concentration. However, ion implantation can be expensive, potentially causing damage to the source and drain regions, resulting in high junction leakage, and can be difficult to integrate, e.g., in-situ processing such as in-situ cleaning, with subsequent processes such as deposition or annealing.

Therefore, what needed are methods that allow for low contact resistances that can be easily integrated with CMOS process flow during semiconductor processing and manufacturing.

### SUMMARY

In some embodiments, methods to improve contact resistance, for example, to a semiconductor region such as a source or a drain region are disclosed. The methods can include depositing a layer on a substrate, wherein the layer can include a first element to form a silicide with the substrate and a second element to lower a contact resistance between the silicide and the substrate. The first element can include titanium to form titanium silicide with a silicon or germanium substrate, cobalt to form cobalt silicide with the substrate, nickel to form nickel silicide with the substrate, nickel platinum to form nickel platinum silicide with the substrate. The second element can include sulfur, selenium or tellurium, which can act to improve a contact resistance between the silicide layer and the substrate, for example, by enhancing trap assisted tunneling or by lowering the Schottky barrier height between the silicide layer and the substrate.

In some embodiments, the methods can include depositing a first layer on a substrate, wherein the first layer can include sulfur, selenium or tellurium, which can migrate to the substrate surface to improve a contact resistance with the substrate. The methods can include depositing a second layer on the first layer, wherein the second layer can include titanium, cobalt, nickel and/or platinum. The methods can include annealing the substrate with the first and second layers to form a silicide layer, together with an interface layer containing sulfur (S), selenium (Se) or tellurium (Te). For example, a second layer containing titanium can form titanium silicide with a silicon or germanium substrate, cobalt to form cobalt silicide with the substrate, nickel to form nickel silicide with the substrate, nickel platinum to form nickel platinum silicide with the substrate.

In some embodiments, the methods can include depositing a layer on a substrate, wherein the layer can include titanium, cobalt, nickel and/or platinum. The methods can include annealing the substrate to promote a reaction between titanium, cobalt, nickel and/or platinum with the substrate to form a silicide layer. For example, a layer containing titanium can form titanium silicide with a silicon or germanium substrate, cobalt to form cobalt silicide with the substrate, nickel to form nickel silicide with the substrate, nickel platinum to form nickel platinum silicide with the substrate.

In some embodiments, the methods can include depositing a first layer and a second layer on a substrate, wherein the first layer can include titanium, cobalt, nickel and/or platinum, and wherein the second layer can include sulfur, selenium and/or tellurium, which can migrate to the substrate surface to improve a contact resistance with the substrate. The methods can include annealing the substrate with the first and second layers to form a silicide layer, together with an interface layer containing sulfur, selenium or tellurium.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 illustrates an example of a semiconductor device according to some embodiments.

FIGS. 2A-2C illustrate an example of a finFET device structure according to some embodiments.

FIGS. 3A-3B illustrate an example of a process sequence for forming a contact with low contact resistance according to some embodiments.

FIGS. 4A-4B illustrate examples of process flow charts for forming a semiconductor device according to some embodiments.

FIGS. 5A-5B illustrate examples of process flow charts for forming a semiconductor device according to some embodiments.

FIG. 6 illustrates another example of a process flow chart for forming a semiconductor device according to some embodiments.

FIGS. 7A-7B illustrate an example of a process sequence for forming a contact with low contact resistance according to some embodiments.

FIG. 8 illustrates an example of a process flow chart for forming a semiconductor device according to some embodiments.

FIG. 9 illustrates an example of a process flow chart for forming a semiconductor device according to some embodiments.

FIG. 10 illustrates an example of a process flow chart for forming a semiconductor device according to some embodiments.

FIGS. 11A-11B illustrate an example of a process sequence for forming a contact with low contact resistance according to some embodiments.

FIG. 12 illustrates an example of process flow charts for forming a semiconductor device according to some embodiments.

FIG. 13 illustrates another example of a process flow chart for forming a semiconductor device according to some embodiments.

FIGS. 14A-14B illustrate an example of a process sequence for forming a contact with low contact resistance according to some embodiments.

FIG. 15 illustrates an example of a process flow chart for forming a semiconductor device according to some embodiments.

FIGS. 16A-16D illustrate an exemplary process flow for forming a semiconductor device according to some embodiments.

FIG. 17 illustrates an example of process system according to some embodiments.

FIG. 18 illustrates an example of process system according to some embodiments.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

In some embodiments, methods to incorporate dopants into silicon or germanium source and drain regions to improve the contact resistance of the source/drain regions are disclosed. Dopants of sulfur, selenium or tellurium can be introduced to the source/drain regions to form an interface layer on the source/drain region, for example, between the source/drain regions and a silicide layer. The reduction in contact resistance can be due to enhanced trap assisted tunneling in the depletion region near the contact. The reduction in contact resistance can also be due to lowering the electron Schottky barrier height by creating donor defect levels, e.g., about 0.3 eV, below the silicon or germanium conduction band, hence pinning the Fermi level closer to the silicon or germanium conduction band.

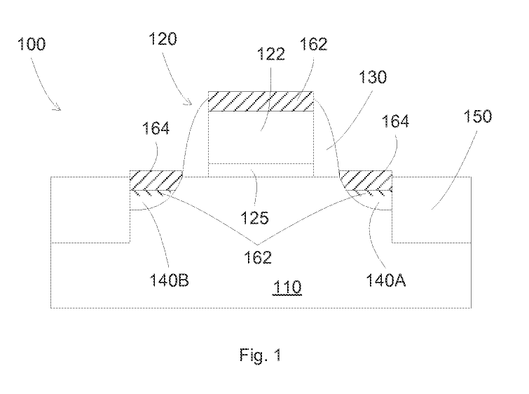

FIG. 1 illustrates an example of a semiconductor device according to some embodiments. A transistor structure 100 is formed on a substrate 110, including isolation regions 150 to isolate the neighboring devices, source and drain regions 140A and 140B sandwiching a gate electrode 120 having a gate dielectric 125 and a gate conductor 122. Spacers 130 cover the sidewalls of the gate electrode 120. The substrate 110 can be a semiconductor substrate, or any substrates having a layer of semiconductor layer. For example, the substrate can be a single crystal silicon substrate. The substrate can be a silicon-germanium substrate, or can have a silicon germanium layer disposed on top. The substrate can also be a germanium substrate, or a silicon carbide substrate. The gate conductor can include doped polysilicon. The top surfaces of the gate electrode 120 and the source and drain regions 140A and 140B can be exposed. FIG. 1 shows a metal-oxide-semiconductor field effect transistor (MOSFET) structure 100, but the invention is not so limited, and can include any transistor structure, such as bipolar transistors, fin transistors or double gate transistors. In addition, the process flow describes a silicidation process for gate electrode 120 and on source and drain regions 140A and 140B, but the invention is not so limited, and can include silicidation for any combination, for example, for only for the gate electrode 120, or only for the source or drain regions 140A or 140B.

The silicide 164, such as TiSi₂, CoSi₂, NiSi, or NiPtSi, can form low contact resistance with the highly doped source and drain regions 140A/140B. To further improve, e.g., lowering, the contact resistance, a dopant layer 162 can be formed between the silicide layer 164 and the source/drain region 140A/140B. In some embodiments, deposition processes to form the dopant layer 162 are disclosed. The dopant can include elements of group VIA of the periodic table, such as S, Se, or Te for n-doped source and drain regions, and elements of group IIA of the periodic table, such as Mg, Ca, Sr, or Ba for p-doped source and drain regions. The dopant can passivate the free surface dangling bonds of the silicon or germanium based source and drain regions. Further, the dopant layer can lower the Schottky barrier between the silicide and the semiconductor contact, further improving the tunneling current at the source/drain regions. The thickness of the dopant layer can be less than about 10 nm. The thickness of the dopant layer can be greater than about 1 monolayer, e.g., 0.3 nm.

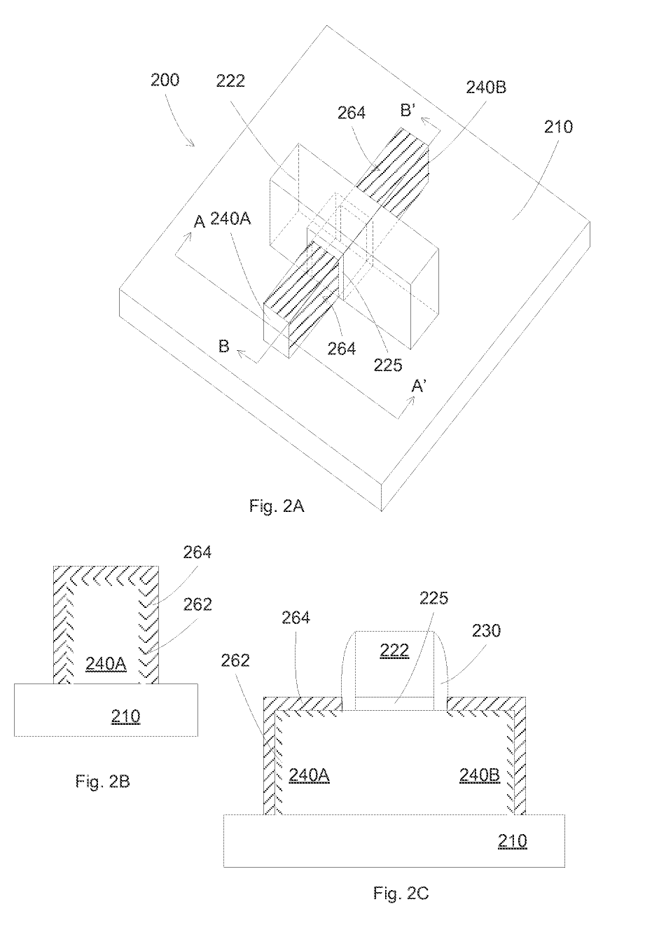

FIGS. 2A-2C illustrate an example of a finFET device structure according to some embodiments. FIG. 2A illustrates a finFET device 200 having a semiconductor body having a fin shape formed on a substrate 210. Source/drain regions 240A/240B can be formed at opposite ends of the semiconductor body. A gate dielectric 225 can be formed on a portion between the source and drain regions 240A/240B, which becomes a channel region of the finFET device. A gate electrode 222 can be formed on the gate dielectric 225. The source/drain regions 240A/240B can be doped, for example, with p-type or n-type dopants to form p-type or n-type devices. The doping of the source/drain regions can be accomplished by doping the whole semiconductor body, using the gate electrode 222 to act as a mask to prevent the channel region from being doped. As shown, the gate dielectric 225 and the gate electrode 222 surround the channel on three sides, forming a tri-gate finFET device. Alternatively, a double-date finFET device can be formed if the gate dielectric and the gate electrode are only present at opposite sides, e.g., left and right without the top side. This can be accomplished by thickening the dielectric portion at the top side of the gate dielectric 225, eliminating or reducing the influence of the gate electrode 222 to the channel region from the top side.

FIG. 2B shows the cross-sectional view of the finFET device across line A-A′ through the source or drain region 240A. The source or drain region 240A is disposed on the substrate 210, and can include a silicide layer 264 together with a dopant layer 262 surrounding the three sides facing the three gate regions of the gate dielectric and electrode. FIG. 2C shows the cross-sectional view of the finFET device across line B-B′ through the gate electrode 222. The source and drain region 240A/240B is disposed on the substrate 210, separating by the channel region under the gate dielectric 225 and the gate electrode 222. The source and drain region 240A/240B and can include a silicide layer 264 together with a dopant layer 262, which can be separated from the gate dielectric. and gate electrode by a spacer 230.

A deposition process, e.g., physical vapor deposition (PVD), chemical vapor deposition (CVD), or atomic layer deposition (ALD), can be used to form the silicide layer 264 and dopant layer 262 on the finFET device. An annealing process can follow the deposition process to form the silicide layer 264 and to diffuse and segregate the dopant to the interface of the source/drain regions.

In some embodiments, methods to improve contact resistance, for example, to a semiconductor region such as a source or a drain region are disclosed. The methods can include depositing a layer on a substrate, wherein the layer can include a first element to form a silicide with the substrate and a second element to lower a contact resistance between the silicide and the substrate. The first element can include titanium to form titanium silicide with a silicon or germanium substrate, cobalt to form cobalt silicide with the substrate, nickel to form nickel silicide with the substrate, nickel platinum to form nickel platinum silicide with the substrate. The second element can include sulfur, selenium or tellurium, which can act to improve a contact resistance between the silicide layer and a n-type substrate, for example, by enhancing trap assisted tunneling or by lowering the Schottky barrier height between the silicide layer and the substrate. The second element can include magnesium, calcium, strontium, or barium, which can act to improve a contact resistance between the silicide layer and a p-type substrate. The substrate can include a semiconductor substrate, such as silicon substrates, germanium substrates, silicon germanium substrates, or silicon carbide substrates. The methods can include cleaning the substrate surface before forming the layer, including cleaning in-situ, e.g., without exposing the surface to an outside ambient after the cleaning process.

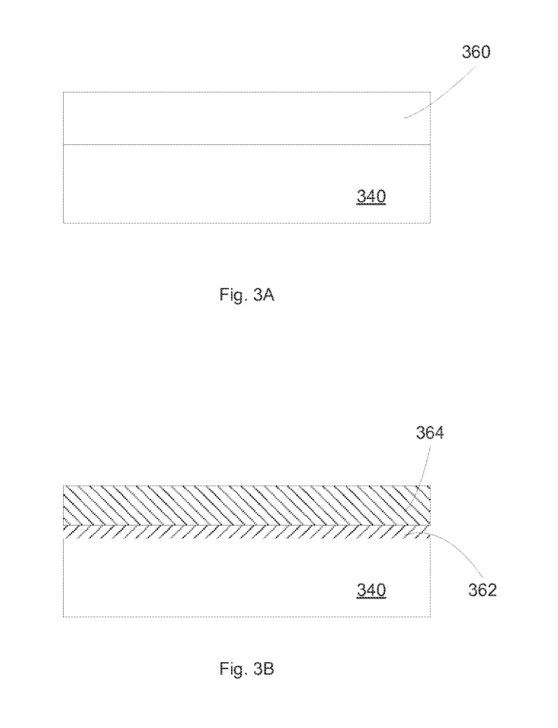

FIGS. 3A-3B illustrate an example of a process sequence for forming a contact with low contact resistance according to some embodiments. In FIG. 3A, a layer 360 can be deposited on a semiconductor substrate region 340. The deposition process can include a physical vapor deposition, a chemical vapor deposition, an atomic layer deposition, or any other deposition technique. The layer can have at least one element that can form a silicide with the substrate, such as titanium, cobalt, nickel, or nickel platinum to form titanium silicide, cobalt silicide, nickel silicide or nickel platinum silicide with a silicon containing substrate. The layer can also have a dopant element to diffuse to the substrate to form a dopant layer, such as Mg, Ca, Sr, or Ba for p-type substrate or sulfur, selenium, or tellurium for n-type substrate.

In some embodiments, the semiconductor substrate region 340 can be a source or drain region in a semiconductor device, for example, a p-type or n-type doped semiconductor layer. The semiconductor substrate region 340 can be included in a transistor device, with a gate dielectric and a gate electrode. The silicide layer can form a Schottky or Ohmic contact with the semiconductor layer, with the dopant modulating, e.g., lowering, the Schottky barrier height for lower contact resistance.

In FIG. 3B, an anneal process can be used, e.g., the substrate can be exposed to a high temperature. The silicide element in the layer 360, e.g., titanium, cobalt, nickel, or nickel platinum can react with the substrate, e.g., silicon or germanium, to form the silicide layer 364. The dopant can diffuse to the substrate, and then can segregate at the interface of the substrate region 340 and the silicide layer 364, for example, to form a dopant layer 362.

One or two annealing processes can be used. For example, a first anneal can be used to form a silicide, and a second anneal in a reactive ambient can be used to diffuse and segregate the dopant at the interface. Alternatively, a single anneal in a reactive ambient can be used to form silicide and diffuse and segregate the dopant at the interface.

For example, the annealing can include a first and second anneal processes, which can be used to fabricate a silicide layer. A first rapid thermal process or a laser annealing process can react the metal, e.g., nickel and platinum in a nickel platinum layer, with the silicon in the source/drain regions. The first rapid thermal process can include an anneal in nitrogen ambient, at a temperature less than 380 C for less than one minute. For example, a rapid thermal process can include annealing at 300 C for about 30 seconds. The substrate surface can be cleaned, for example, to remove the unreacted nickel platinum, using a etchant such as dilute nitric acid, or aqua regia. The substrate can then be annealed, for example, by a second rapid thermal process or a laser annealing process, to further reduce the resistance of the nickel platinum silicide. The second rapid thermal process can include an anneal in a nitrogen ambient, at a temperature greater than 300 C for less than one minute. For example, a rapid thermal process can include annealing at 450 C for about 30 seconds.

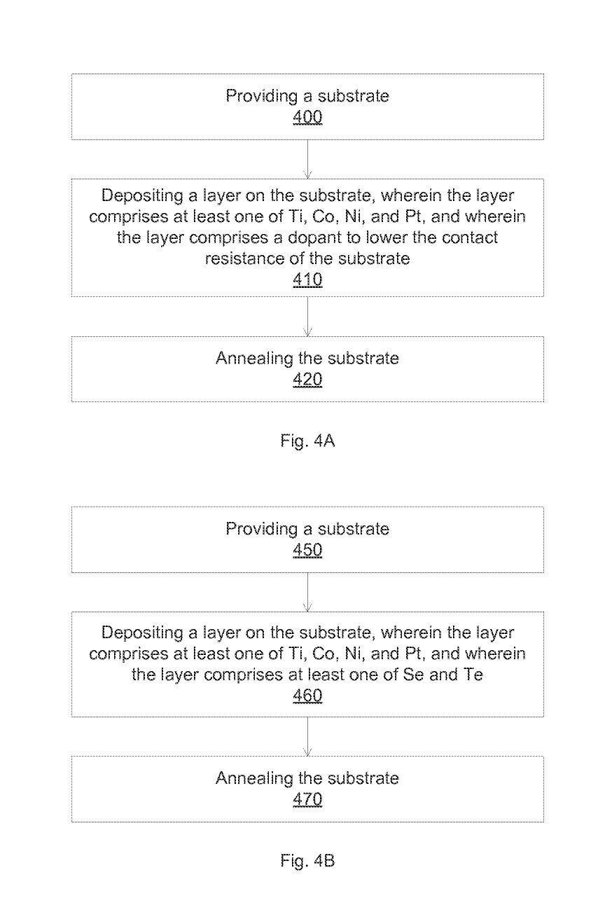

FIGS. 4A-4B illustrate examples of process flow charts for forming a semiconductor device according to some embodiments. In FIG. 4A, a layer is deposited on a semiconductor substrate. The components of the layer include a metal element, which is configured to form a silicide with the semiconductor substrate, and a dopant element, which is configured to diffuse and segregate with the semiconductor substrate. After an annealing process, a silicide layer is formed on the semiconductor substrate, together with a dopant layer at the interface of the silicide layer and the semiconductor substrate. In operation 400, a semiconductor substrate is provided. The substrate can include a semiconductor element, such as silicon, germanium, carbon, or any combination thereof, such as silicon germanium or silicon carbide. The substrate can be a region such as the source, drain, or gate electrode of a semiconductor device, e.g., a semiconductor device is partially fabricated, including device isolation, device gate stack, device source and drain formation, and spacers between the source and drain and the gate stack.

In operation 410, a layer is deposited on the substrate. The deposition process can include a physical vapor deposition, a chemical vapor deposition, an atomic layer deposition, or any other deposition technique. The layer can include a first element that can form a silicide with the substrate, such as a metal element, or a metal element of titanium, cobalt, nickel, or nickel platinum. The layer can also include a second element that can diffuse to the substrate. The second element can include semiconductor dopants, which can provide dopant to the substrate. For example, n-type dopant can include sulfur, selenium, or tellurium, and p-type dopant can include Mg, Ca, Sr, or Ba.

In operation 420, the substrate is annealed. The annealing process can be optimized for forming the silicide layer, e.g., a first low temperature anneal to react the metal in the deposited layer with the substrate, and a second high temperature anneal to convert the reacted silicide to a low resistance silicide layer. The silicidation anneal process can also drive the dopant to the substrate and segregate it at the interface. Optionally, the annealing process can include a third anneal to optimize the dopant diffusion and segregation process. Additional processes can be included, for example, the substrate can be cleaned before depositing the layer. Further, process variations can be used, for example, an in-situ cleaning/deposition or an in-situ deposition/annealing, e.g., the in-situ sequence allows maintaining a clean environment between the steps, reducing potential contamination.

In FIG. 4B, a layer is deposited on a semiconductor substrate. The components of the layer include at least one of Ti, Co, Ni, and Pt, together with a dopant of Se or Te. After an annealing process, a silicide layer is formed on the semiconductor substrate, together with a dopant layer at the interface of the silicide layer and the semiconductor substrate. In operation 450, a semiconductor substrate is provided. In operation 460, a layer is deposited on the substrate. The layer can include a first element of titanium, cobalt, nickel, or nickel platinum. The layer can also include a second element of Se, or Te. In operation 420, the substrate is annealed to form a silicide layer with low contact resistance, e.g., due to the dopant interfacial layer. Additional processes can be included, for example, the substrate can be cleaned before depositing the layer. Further, process variations can be used, for example, an in-situ cleaning/deposition or an in-situ deposition/annealing, e.g., the in-situ sequence allows maintaining a clean environment between the steps, reducing potential contamination.

The methods can include sputter depositing a layer from one or more targets. For example, a single target of titanium, cobalt, nickel, or nickel platinum and sulfur, selenium, or tellurium can be used to sputter depositing a layer of TiS, TiSe, TiTe, CoS, CoSe, CoTe, NiS, NiSe, NiTe, NiPtS, NiPtSe, or NiPtTe. The composition of the target can include less than 10 at % sulfur, selenium or tellurium, such as between 2 and 10 at %. Multiple targets can be used in a co-sputtering process, such as a target of titanium, cobalt, nickel, or nickel platinum and a target of sulfur, selenium, or tellurium.

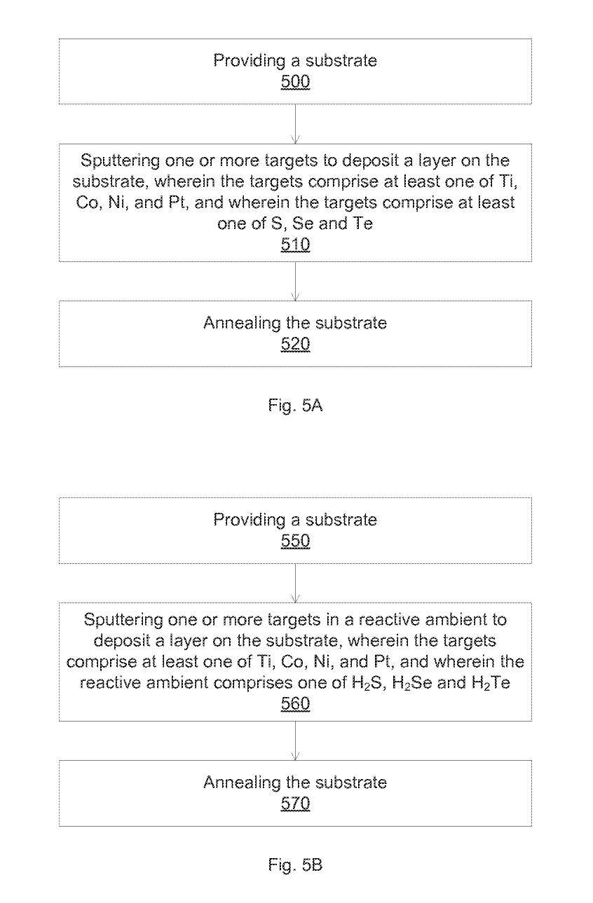

FIG. 5A illustrates an example of a process flow chart for forming a semiconductor device according to some embodiments. In operation 500, a semiconductor substrate is provided. In operation 510, a layer is sputter deposited on the substrate from one or more targets. The targets can include a first element that can form a silicide with the substrate, such as a metal element, or a metal element of titanium, cobalt, nickel, or nickel platinum. One or more targets can be used, for example, a nickel platinum target can be used for sputter depositing nickel platinum. For example, a compound target having 95 at % to 85 at % nickel and 5 at % to 15 at % platinum can be used to sputter nickel platinum. A nickel target and a platinum target can be used to co-deposit nickel platinum.

The targets can also include a second element that can diffuse to the substrate. The second element can include semiconductor dopants, which can provide a dopant to the substrate. For example, n-type dopant can include sulfur, selenium, or tellurium, and p-type dopant can include Mg, Ca, Sr, or Ba. One or more targets can be used, for example, a single target having 95-80 at % nickel, 5-20 at % platinum, and 2-10 at % Te can be used to deposit a NiPtTe layer. Alternatively, multiple targets can be used with proper operating conditions to achieve a desired composition. For example, a target of Ni, a target of platinum, and a target of tellurium can be used to deposit a NiPtTe layer. In operation 520, the substrate is annealed. The annealing process can be optimized for forming the silicide layer with low contact resistance.

The methods can include sputter depositing a layer from one or more targets in a reactive ambient containing a dopant, such as sulfur, selenium or tellurium. For example, a target of titanium, cobalt, nickel, or nickel platinum can be used with a reactive gas of H₂S, H₂Se, or H₂Te. The plasma environment can excite the reactive gas to sputter deposit a layer of TiS, TiSe, TiTe, CoS, CoSe, CoTe, NiS, NiSe, NiTe, NiPtS, NiPtSe, or NiPtTe. Additional processes can be included, for example, the substrate can be cleaned before depositing the layer. Further, process variations can be used, for example, an in-situ cleaning/deposition or an in-situ deposition/annealing, e.g., the in-situ sequence allows maintaining a clean environment between the steps, reducing potential contamination.

FIG. 5B illustrates another example of a process flow chart for forming a semiconductor device according to some embodiments. In operation 550, a semiconductor substrate is provided. In operation 560, a layer is sputter deposited on the substrate from one or more targets in a reactive ambient. The targets can include an element that can form a silicide with the substrate, such as a metal element, or a metal element of titanium, cobalt, nickel, or nickel platinum. The sputtering process can be performed in a reactive ambient, such as a plasma ambient containing the reactive gas of H₂S, H₂Se or H₂Te. The dopant, e.g., sulfur, selenium, or tellurium can be dissociated from the reactive gas, and can be deposited or diffused to the substrate or to the deposited layer. For example, the reactive gas can react with the sputter species to form a compound layer to be deposited on the substrate. A nickel target can provide nickel atoms, which can react with the energetic S of the reactive gas H₂S, for example, to deposit a layer of NiS on the substrate. In operation 570, the substrate is annealed. The annealing process can be optimized for forming the silicide layer with low contact resistance.

The methods can include an atomic layer deposition process, for example, of TiSe, TiTe, CoSe, CoTe, NiSe, NiTe, NiPtSe, or NiPtTe. The atomic layer deposition process can include a sequential exposure of the substrate to multiple precursors, such as a first precursor containing titanium, cobalt, nickel, or nickel platinum, and a second precursor containing H₂Se or H₂Te. Alternatively, the second precursor can include a precursor containing Mg, Ca, Sr, or Ba for providing dopants to p-type substrates. Additional processes can be included, for example, the substrate can be cleaned before depositing the layer. Further, process variations can be used, for example, an in-situ cleaning/deposition or an in-situ deposition/annealing, e.g., the in-situ sequence allows maintaining a clean environment between the steps, reducing potential contamination.

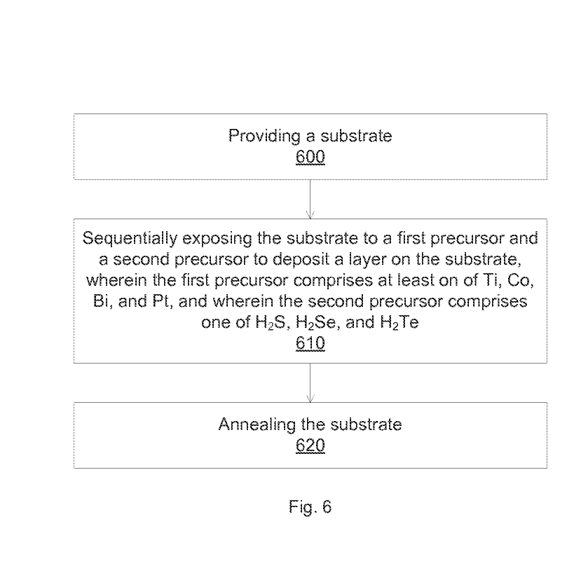

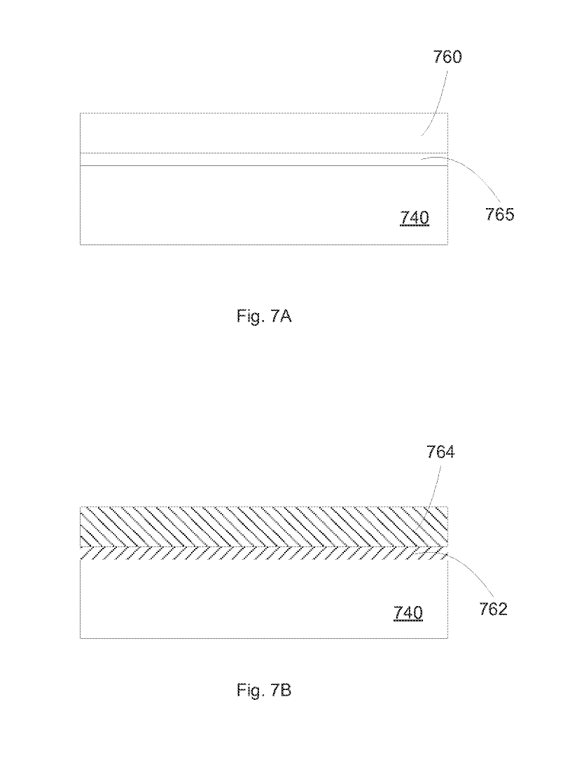

FIG. 6 illustrates another example of a process flow chart for forming a semiconductor device according to some embodiments. In operation 600, a semiconductor substrate is provided. In operation 610, a layer is deposited on the substrate by an atomic layer deposition process, including a sequential exposure of the substrate to a first precursor and a second precursor. The first precursor can include an element that can form a silicide with the substrate, such as a metal element, or a metal element of titanium, cobalt, nickel, or nickel platinum. The second precursor can include a dopant, such as Se or Te for n-type substrate and Mg, Ca, Sr, or Ba for p-type substrate. For example, the second precursor can include H₂Se or H₂Te. In operation 620, the substrate is annealed. The annealing process can be optimized for forming the silicide layer with low contact resistance. The annealing can include a rapid thermal annealing process or a laser annealing process.

In some embodiments, the methods can include depositing a first layer and a second layer on a substrate, wherein the first layer can include titanium, cobalt, nickel and/or platinum, and wherein the second layer can include a compound layer including elements of magnesium, calcium, strontium, or barium for p-type substrate or sulfur, selenium or tellurium for n-type substrate, which can migrate to the substrate surface to improve the contact resistance with the substrate. The first layer can be deposited on the second layer on the substrate, for example, forming a layer of titanium, cobalt, nickel, or nickel platinum on a layer of Ge₂Sb₂Te₅. Alternatively, the second layer can be deposited on the first layer on the substrate, for example, forming a layer of Ge₂Sb₂Te₅ on a layer of titanium, cobalt, nickel, or nickel platinum. In addition, the methods can include annealing the substrate with the first and second layers to form a silicide layer, together with a dopant interface layer.

In some embodiments, the methods can include depositing a first layer on a substrate, wherein the first layer can include a dopant such as sulfur, selenium or tellurium, which can migrate to the substrate surface to improve the contact resistance with the substrate. The first layer can be less than 2 nm thick, and can be between 1 and 2 nm thick. The methods can include depositing a second layer on the first layer, wherein the second layer can include titanium, cobalt, nickel and/or platinum, which can react with the substrate to form a silicide layer. The methods can include annealing the substrate with the first and second layers to form a silicide layer, together with an interface layer containing the dopant such as sulfur, selenium or tellurium. For example, a second layer containing titanium can form titanium silicide with a silicon or germanium substrate, cobalt to form cobalt silicide with the substrate, nickel to form nickel silicide with the substrate, nickel platinum to form nickel platinum silicide with the substrate. The contact resistance of the silicide layer with the substrate can be improved, e.g., lowered, due to the dopant layer, for example, which can provide trap charges and lower the Schottky barrier height between the silicide layer and the semiconductor substrate.

FIGS. 7A-7B illustrate an example of a process sequence for forming a contact with low contact resistance according to some embodiments. In FIG. 7A, a first layer 765 can be deposited on a semiconductor substrate 740. The first layer can have a dopant element to diffuse to the substrate to form a dopant layer, such as Mg, Ca, Sr, or Ba for p-type substrate or sulfur, selenium, or tellurium for n-type substrate. A second layer 760 can be deposited on the first layer 765. The second layer can have at least one element that can form a silicide with the substrate, such as titanium, cobalt, nickel, or nickel platinum to form titanium silicide, cobalt silicide, nickel silicide or nickel platinum silicide with a silicon containing substrate.

In FIG. 7B, an anneal process can be used, e.g., the substrate can be exposed to a high temperature. The dopant in the first layer 765 can diffuse to the substrate, and then can segregate at the interface of the substrate 740, for example, to form a dopant layer 762. The silicide element in the second layer 760, e.g., titanium, cobalt, nickel, or nickel platinum can react with the substrate, e.g., silicon or germanium, to form the silicide layer 764.

One or two annealing processes can be used. For example, a first anneal can be used to form a silicide, and a second anneal in a reactive ambient can be used to diffuse and segregate the dopant at the interface. Alternatively, a single anneal in a reactive ambient can be used to form silicide and diffuse and segregate the dopant at the interface.

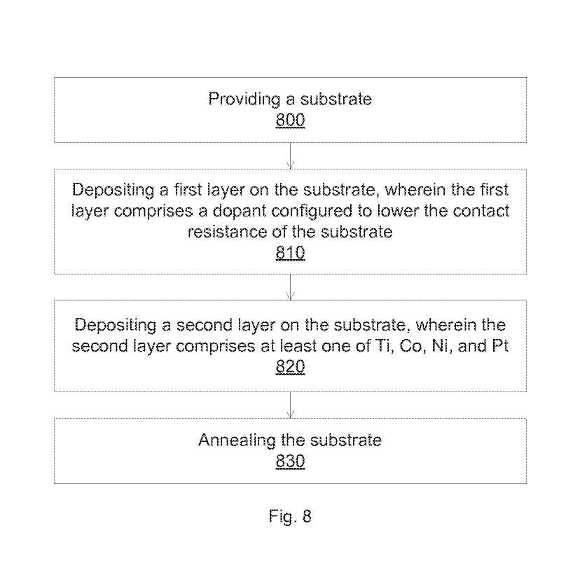

FIG. 8 illustrates an example of process flow charts for forming a semiconductor device according to some embodiments. In operation 800, a semiconductor substrate region is provided. The substrate can include a semiconductor element, such as silicon, germanium, carbon, or any combination thereof, such as silicon germanium or silicon carbide. The substrate region can be the source, drain, or gate electrode of a semiconductor device, e.g., a semiconductor device is partially fabricated, including device isolation, device gate stack, device source and drain formation, and spacers between the source and drain and the gate stack.

In operation 810, a first layer is deposited on the substrate. The deposition process can include a physical vapor deposition, a chemical vapor deposition, an atomic layer deposition, or any other deposition techniques. The first layer can include semiconductor dopants, which are configured to lower a contact resistance of the substrate. For example, n-type dopant can include sulfur, selenium, or tellurium, and p-type dopant can include Mg, Ca, Sr, or Ba.

In operation 820, a second layer is deposited on the substrate. The deposition process can include a physical vapor deposition, a chemical vapor deposition, an atomic layer deposition, or any other deposition technique. The second layer can include a first element that can form a silicide with the substrate, such as a metal element, or a metal element of titanium, cobalt, nickel, or nickel platinum.

In operation 830, the substrate is annealed. The annealing process can be optimized for forming the silicide layer. The silicidation annealing process can also drive the dopant to the substrate and segregate them at the interface. Optionally, the annealing process can include a third annealing to optimize the dopant diffusion and segregation process. Additional processes can be included, for example, the substrate can be cleaned before depositing the layer. Further, process variations can be used, for example, an in-situ cleaning/deposition, an in-situ deposition between the first and second layers, or an in-situ deposition/annealing, e.g., the in-situ sequence allows maintaining a clean environment between the steps, reducing potential contamination.

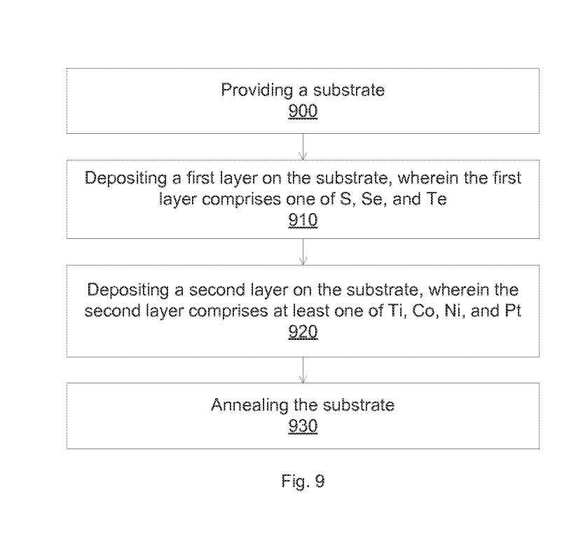

FIG. 9 illustrates another example of a process flow chart for forming a semiconductor device according to some embodiments of the present invention. In operation 900, a semiconductor substrate is provided. In operation 910, a first layer is deposited on the substrate. The first layer can include a semiconductor dopant, such as sulfur, selenium, or tellurium for n-type substrates, and Mg, Ca, Sr, or Ba for p-type substrates. The deposition process can include a physical vapor deposition, a chemical vapor deposition, an atomic layer deposition, or any other deposition technique. For example, a layer of S (or other dopants) can be sputter deposited on the substrate. A plasma deposition can be used, for example, using a reactive gas such as H₂S (or H₂Se or H₂Te) to deposit a layer of sulfur (or Se or Te) on the substrate. The plasma can be a remote plasma, or a radio frequency (RF) plasma, for example, generated from a parallel plate plasma reactor or an inductive coupled plasma reactor. The first layer can be formed by exposing the substrate to a reactive element of sulfur, selenium or tellurium, such as atomic sulfur, atomic selenium or atomic tellurium. The reactive element of sulfur, selenium or tellurium can be generated by a remote plasma or an RF plasma (at frequency 13.56 MHz, 2 MHz, or other frequencies) using the gases of H₂S, H₂Se, or H₂Te, respectively.

In operation 920, a second layer is deposited on the first layer. The deposition process can include a physical vapor deposition, a chemical vapor deposition, an atomic layer deposition, or any other deposition technique. The second layer can include a first element that can form a silicide with the substrate, such as a metal element, or a metal element of titanium, cobalt, nickel, or nickel platinum. The second layer can be formed by a sputter deposition process utilizing one or more targets. For example, a target of titanium, cobalt, nickel, or nickel platinum can be used to sputter depositing a layer of titanium, cobalt, nickel, or nickel platinum, respectively. Alternatively, the second layer can be formed by a chemical vapor deposition process using one or more precursors.

In operation 930, the substrate, having the first and second layers deposited thereon, is annealed. The annealing process can be optimized for forming the silicide layer. The silicidation annealing process can also drive the dopant to the substrate and segregate them at the interface. Optionally, the annealing process can include a third annealing to optimize the dopant diffusion and segregation process. Additional processes can be included, for example, the substrate can be cleaned before depositing the layer. Further, process variations can be used, for example, an in-situ cleaning/deposition, an in-situ deposition between the first and second layers, or an in-situ deposition/annealing, e.g., the in-situ sequence allows maintaining a clean environment between the steps, reducing potential contamination.

In some embodiments, the methods can include depositing a first layer containing a compound, e.g., a mixture or an alloy, that includes a dopant, e.g., sulfur, selenium, or tellurium for n-type semiconductor substrates and Mg, Ca, Sr, or Ba for p-type semiconductor substrates. For example, a thin layer of Ge₂Sb₂Te₅ can be used as a source of tellurium as a dopant for n-type semiconductor substrates. The thickness of the Ge₂Sb₂Te₅ layer can be between 2 and 100 nm.

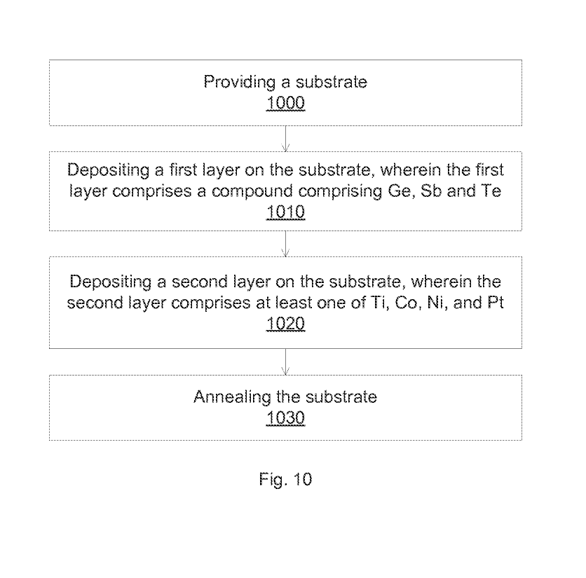

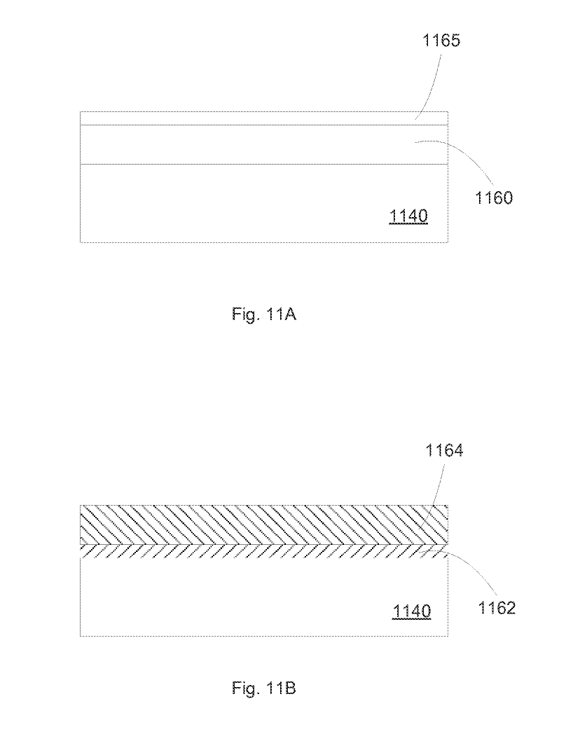

FIG. 10 illustrates an example of a process flow chart for forming a semiconductor device according to some embodiments. In operation 1000, a semiconductor substrate is provided. In operation 1010, a first layer is deposited on the substrate. The first layer can include a compound of Ge, Sb, and Te (GST). An example of a GST includes Ge₂Sb₂Te₅. For example, a first layer can include a thin layer of GST. The GST layer can be deposited by sputtering, or by an atomic layer deposition process, including a sequential exposure of the substrate to multiple precursors. A first precursor can include a germanium-containing precursor, such as GeCl₂.C₄H₈O₂. A second precursor can include an antimony-containing precursor, such as SbCl₃. A third precursor can include a tellurium-containing precursor, such as an alkyl silyl tellurium compound ((R₃Si)₂Te), e.g., (Me₃Si)₂Te or (Et₃Si)₂Te.

In operation 1020, a second layer is deposited on the first layer. The deposition process can include a physical vapor deposition, a chemical vapor deposition, an atomic layer deposition, or any other deposition technique. The second layer can include a first element that can form a silicide with the substrate, such as a metal element, or a metal element of titanium, cobalt, nickel, or nickel platinum. The second layer can be formed by a sputter deposition process utilizing one or more targets. For example, a target of titanium, cobalt, nickel, or nickel platinum can be used to sputter depositing a layer of titanium, cobalt, nickel, or nickel platinum, respectively. Alternatively, the second layer can be formed by a chemical vapor deposition process using one or more precursors.

In operation 1030, the substrate, having the first and second layers deposited thereon, is annealed. The annealing process can be optimized for forming the silicide layer. The silicidation annealing process can also drive the dopant to the substrate and segregate them at the interface. Optionally, the annealing process can include a third annealing to optimize the dopant diffusion and segregation process. Additional processes can be included, for example, the substrate can be cleaned before depositing the layer. Further, process variations can be used, for example, an in-situ cleaning/deposition, an in-situ deposition between the first and second layers, or an in-situ deposition/annealing, e.g., the in-situ sequence allows maintaining a clean environment between the steps, reducing potential contamination.

In some embodiments, the methods can include forming a first layer on a substrate, wherein the first layer can include titanium, cobalt, nickel and/or platinum. The methods can include depositing a second layer on the first layer, wherein the second layer can include a dopant such as sulfur, selenium and/or tellurium, which can migrate to the substrate surface to improve a contact resistance with the substrate. The methods can include annealing the substrate with the first and second layers to form a silicide layer, together with an interface layer containing sulfur, selenium or tellurium.

FIGS. 11A-11B illustrate an example of a process sequence for forming a contact with low contact resistance according to some embodiments. In FIG. 11A, a first layer 1160 can be deposited on a semiconductor substrate 1140. The first layer can have at least an element that can form a silicide with the substrate, such as titanium, cobalt, nickel, or nickel platinum to form titanium silicide, cobalt silicide, nickel silicide or nickel platinum silicide with a silicon containing substrate. A second layer 1165 can be deposited on the first layer 1160. The second layer can have a dopant element to diffuse to the substrate to form a dopant layer, such as Mg, Ca, Sr, or Ba for p-type substrate or sulfur, selenium, or tellurium for n-type substrate.

In FIG. 11B, an anneal process can be used, e.g., the substrate can be exposed to a high temperature ambient. The silicide element in the first layer 1160, e.g., titanium, cobalt, nickel, or nickel platinum can react with the substrate, e.g., silicon or germanium, to form the silicide layer 1164. The dopant in the second layer 1165 can diffuse through the silicide layer 1164 to the substrate, and then can segregate at the interface of the substrate 1140, for example, to form a dopant layer 1162.

One or two annealing processes can be used. For example, a first anneal can be used to form a silicide, and a second anneal in a reactive ambient can be used to diffuse and segregate the dopant at the interface. Alternatively, a single anneal in a reactive ambient can be used to form silicide and diffuse and segregate the dopant at the interface.

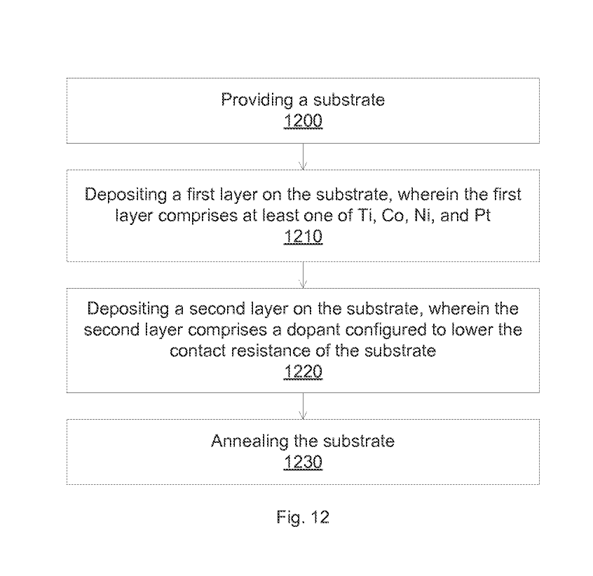

FIG. 12 illustrates an example of process flow charts for forming a semiconductor device according to some embodiments of the present invention. In operation 1200, a semiconductor substrate is provided. The substrate can include a semiconductor element, such as silicon, germanium, carbon, or any combination thereof, such as silicon germanium or silicon carbide. The substrate can be the source, drain, or gate electrode of a semiconductor device, e.g., a semiconductor device is partially fabricated, including device isolation, device gate stack, device source and drain formation, and spacers between the source and drain and the gate stack.

In operation 1210, a first layer is deposited on the substrate. The deposition process can include a physical vapor deposition, a chemical vapor deposition, an atomic layer deposition, or any other deposition technique. The first layer can include an element that can form a silicide with the substrate, such as a metal element, or a metal element of titanium, cobalt, nickel, or nickel platinum.

In operation 1220, a second layer is deposited on the substrate. The deposition process can include a physical vapor deposition, a chemical vapor deposition, an atomic layer deposition, or any other deposition technique. The second layer can include semiconductor dopants, which are configured to lower a contact resistance of the substrate. For example, n-type dopant can include sulfur, selenium, or tellurium, and p-type dopant can include Mg, Ca, Sr, or Ba.

In operation 1230, the substrate is annealed. The annealing process can be optimized for forming the silicide layer. The silicidation annealing process can also drive the dopant to the substrate and segregate them at the interface. Optionally, the annealing process can include a third annealing to optimize the dopant diffusion and segregation process. Additional processes can be included, for example, the substrate can be cleaned before depositing the layer. Further, process variations can be used, for example, an in-situ cleaning/deposition, an in-situ deposition between the first and second layers, or an in-situ deposition/annealing, e.g., the in-situ sequence allows maintaining a clean environment between the steps, reducing potential contamination.

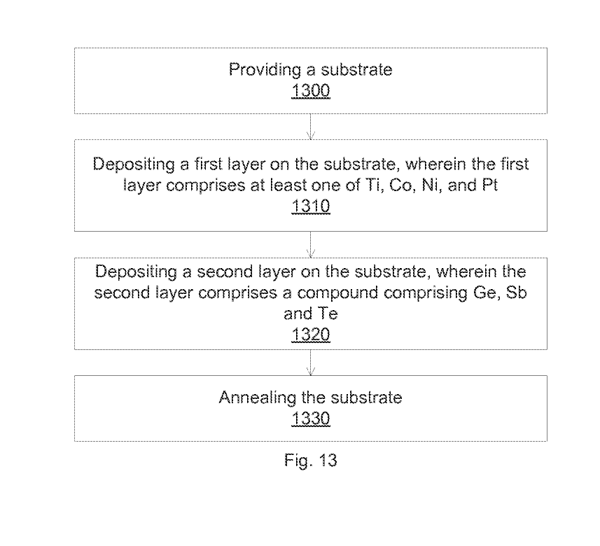

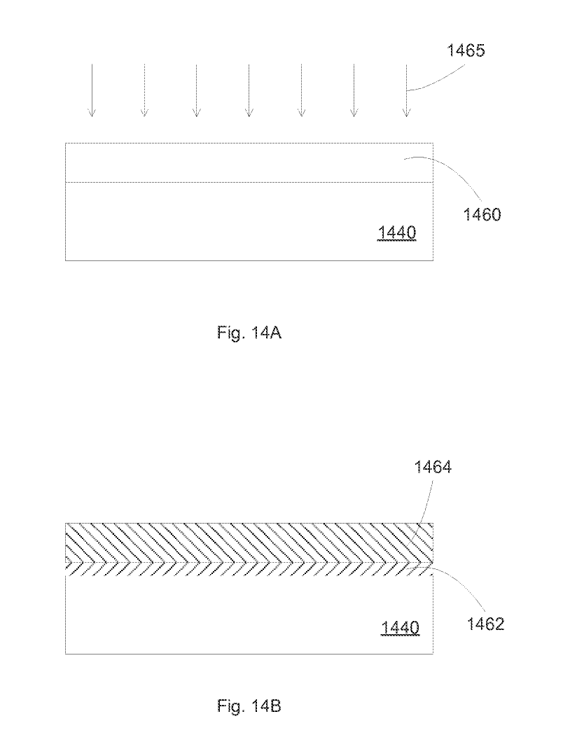

FIG. 13 illustrates another example of a process flow chart for forming a semiconductor device according to some embodiments of the present invention. In operation 1300, a semiconductor substrate is provided. In operation 1310, a first layer is deposited on the substrate. The deposition process can include a physical vapor deposition, a chemical vapor deposition, an atomic layer deposition, or any other deposition technique. The first layer can include an element that can form a silicide with the substrate, such as a metal element, or a metal element of titanium, cobalt, nickel, or nickel platinum. The first layer can be formed by a sputter deposition process utilizing one or more targets. For example, a target of titanium, cobalt, nickel, or nickel platinum can be used to sputter depositing a layer of titanium, cobalt, nickel, or nickel platinum, respectively. Alternatively, the first layer can be formed by a chemical vapor deposition process using one or more precursors.

In operation 1320, a second layer is deposited on the first layer. The second layer can include a semiconductor dopant, such as sulfur, selenium, or tellurium for n-type substrates, and Mg, Ca, Sr, or Ba for p-type substrates. The deposition process can include a physical vapor deposition, a chemical vapor deposition, an atomic layer deposition, or any other deposition technique. For example, a layer of S (or other dopants) can be sputter deposited on the substrate. A plasma deposition can be used, for example, using a reactive gas such as H₂S (or H₂Se or H₂Te) to deposit a layer of sulfur on the substrate. The plasma can be a remote plasma, or a radio frequency (RF) plasma, for example, generated from a parallel plate plasma reactor or an inductive coupled plasma reactor. The first layer can be formed by exposing the substrate to a reactive element of sulfur, selenium or tellurium, such as atomic sulfur, atomic selenium or atomic tellurium. The reactive element of sulfur, selenium or tellurium can be generated by a remote plasma or an RF plasma (at frequency 13.56 MHz, 2 MHz, or other frequencies) using the gases of H₂S, H₂Se, or H₂Te, respectively.

In operation 1330, the substrate, having the first and second layers deposited thereon, is annealed. The annealing process can be optimized for forming the silicide layer. The silicidation annealing process can also drive the dopant to the substrate and segregate them at the interface. Optionally, the annealing process can include a third annealing to optimize the dopant diffusion and segregation process. Additional processes can be included, for example, the substrate can be cleaned before depositing the layer. Further, process variations can be used, for example, an in-situ cleaning/deposition, an in-situ deposition between the first and second layers, or an in-situ deposition/annealing, e.g., the in-situ sequence allows maintaining a clean environment between the steps, reducing potential contamination.

In some embodiments, the methods can include depositing a second layer containing a compound, e.g., a mixture or an alloy, that includes a dopant, e.g., sulfur, selenium, or tellurium for n-type semiconductor substrates and Mg, Ca, or Ba for p-type semiconductor substrates. For example, a thin layer of Ge₂Sb₂Te₅ can be used as a source of tellurium as a dopant for n-type semiconductor substrates. The thickness of the Ge₂Sb₂Te₅ layer can be between 2 and 100 nm.

In some embodiments, the second layer can include a compound of Ge, Sb, and Te (GST). For example, a second layer can include a thin layer of GST, deposited by sputtering or atomic layer deposition. For example, targets including germanium, antimony and tellurium can be used to sputter depositing a compound layer of Ge₂Sb₂Te₅. Alternatively, the second layer can be formed by an atomic layer deposition process, for example, by sequentially exposing the substrate to a plurality of precursors including germanium, antimony and tellurium. A first precursor can include a germanium-containing precursor, such as a germanium chloride compound (GeCl₂.C₂H₈O₂). A second precursor can include an antimony-containing precursor, such as an antimony chloride compound (SbCl₃). A third precursor can include a tellurium-containing precursor, such as an alkyl silyl tellurium compound ((R₃Si)₂Te, e.g., (Me₃Si)₂Te or (Et₃Si)₂Te).

In some embodiments, the methods can include forming a silicide layer on a substrate, such as a titanium silicide, a cobalt silicide, a nickel silicide, or nickel platinum silicide layer. For example, a layer can be deposited on a substrate, wherein the layer can include titanium, cobalt, nickel and/or platinum. The deposited layer can be annealed to promote a reaction between titanium, cobalt, nickel and/or platinum with the substrate to form a silicide layer. For example, a layer containing titanium can form titanium silicide with a silicon or germanium substrate, cobalt to form cobalt silicide with the substrate, nickel to form nickel silicide with the substrate, nickel platinum to form nickel platinum silicide with the substrate.

The methods can also include annealing the substrate in a reactive ambient containing a dopant such as sulfur, selenium or tellurium. For example, the reactive ambient can include a plasma ambient with a reactive gas of H₂S, H₂Se, or H₂Te. The plasma environment can excite the reactive gas to diffuse sulfur, selenium or tellurium element to the silicide layer. The element of sulfur, selenium or tellurium can be segregated at the interface of the substrate to reduce the contact resistance with the substrate.

In some embodiments, the dopant annealing process can be combined with the silicide annealing process. For example, a layer containing titanium, cobalt, nickel and/or platinum can be deposited on a substrate. The deposited layer can be annealed in a reactive ambient containing a dopant. The annealing process can be optimized for forming a silicide layer, together with forming an interface dopant layer.

FIGS. 14A-14B illustrate an example of a process sequence for forming a contact with low contact resistance according to some embodiments. In FIG. 14A, a layer 1460 can be deposited on a semiconductor substrate 1440. The deposition process can include a physical vapor deposition, a chemical vapor deposition, an atomic layer deposition, or any other deposition technique. The layer can have at least an element that can form a silicide with the substrate, such as titanium, cobalt, nickel, or nickel platinum to form titanium silicide, cobalt silicide, nickel silicide or nickel platinum silicide with a silicon containing substrate. Alternatively, a silicide layer can be form on the semiconductor substrate.

In FIG. 14B, a reactive anneal process can be used, e.g., the substrate can be exposed to a high temperature ambient in a reactive ambient containing a dopant, such as sulfur, selenium or tellurium. For example, the reactive ambient can include a plasma ambient with a reactive gas of H₂S, H₂Se, or H₂Te. The plasma environment can excite the reactive gas to diffuse sulfur, selenium or tellurium element to the substrate. The element of sulfur, selenium or tellurium can be segregated at the interface of the substrate, forming a dopant layer 1462 to reduce the contact resistance with the substrate.

In some embodiments, the reactive anneal can be optimized to form a silicide layer 1464 from the deposited layer 1460. Alternatively, an additional annealing process can be performed to form the silicide layer 1464 before the reactive anneal to drive the dopant to the substrate.

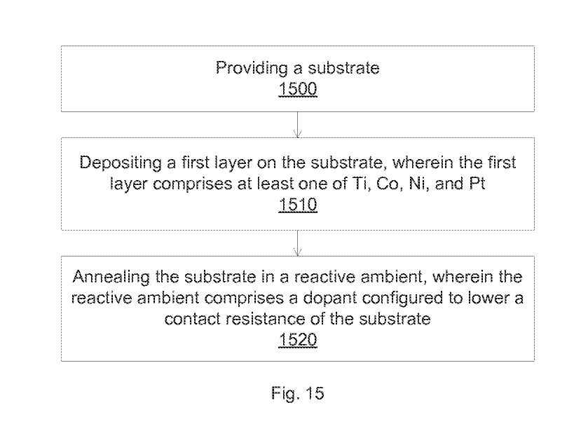

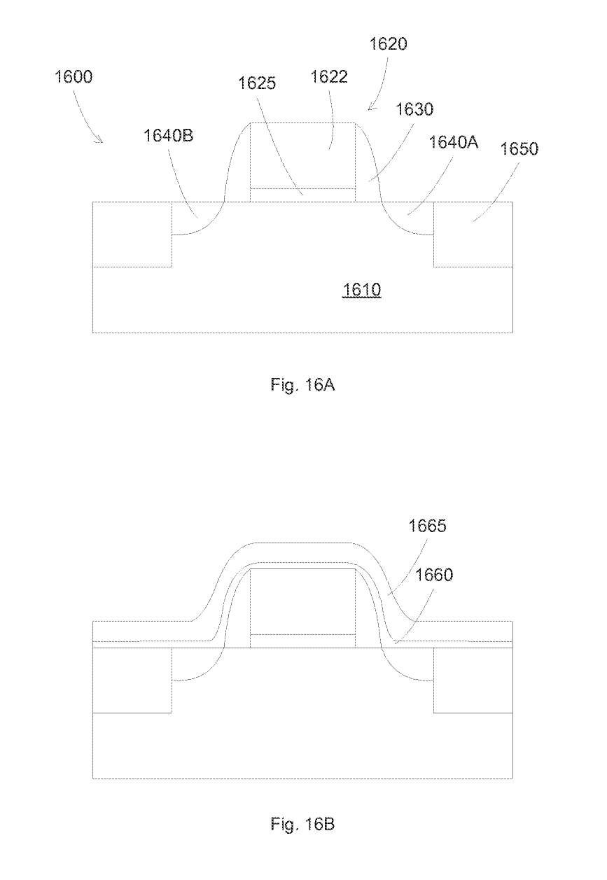

FIG. 15 illustrates an example of a process flow chart for forming a semiconductor device according to some embodiments. In operation 1500, a semiconductor substrate is provided. In operation 1510, a layer is deposited on the substrate. The deposition process can include a physical vapor deposition, a chemical vapor deposition, an atomic layer deposition, or any other deposition technique. The layer can include a first element that can form a silicide with the substrate, such as a metal element, or a metal element of titanium, cobalt, nickel, or nickel platinum. In some embodiments, the layer can be a silicide layer.

In operation 1520, the substrate is annealed in a reactive ambient. For example, the reactive ambient can include a plasma ambient with a reactive gas of H₂S, H₂Se, or H₂Te. The plasma environment can excite the reactive gas to diffuse sulfur, selenium or tellurium element to the substrate. Additional processes can be included, for example, the substrate can be cleaned before depositing the layer. Further, process variations can be used, for example, an in-situ cleaning/deposition, an in-situ deposition between the first and second layers, or an in-situ deposition/annealing, e.g., the in-situ sequence allows maintaining a clean environment between the steps, reducing potential contamination.

In some embodiments, methods to form a semiconductor device are disclosed. The methods can include forming a gate insulating film on a substrate, forming a gate electrode on the gate insulating film, forming a silicide layer on the substrate and a dopant layer at the interface of the silicide layer and the substrate. The silicide layer and the dopant layer can be formed by any of the methods disclosed in the present specification.

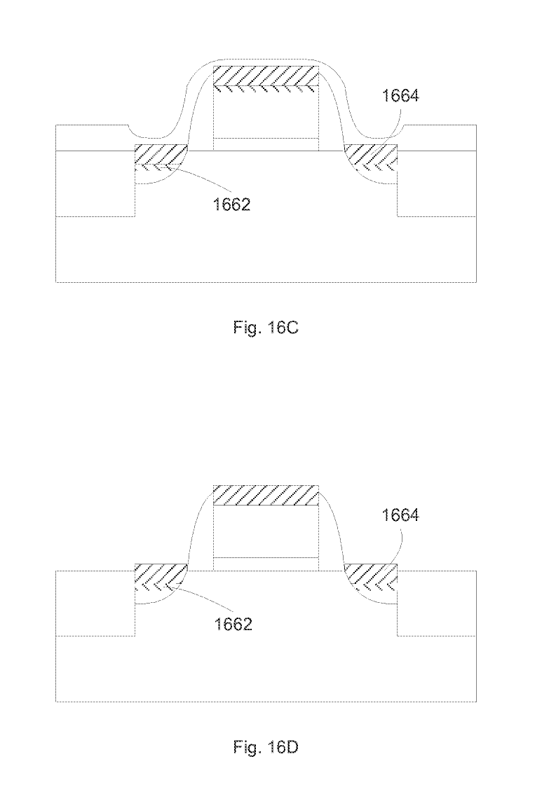

FIGS. 16A-16D illustrate an exemplary process flow for forming a semiconductor device according to some embodiments of the present invention. In FIG. 16A, a transistor structure 1600 is formed on a substrate 1610, including isolation regions 1650 to isolate the neighboring devices, source and drain regions 1640A and 1640B sandwiching a gate electrode 1620 including a gate dielectric 1625 and a gate conductor 1622. Spacers 1630 cover the sidewalls of the gate electrode 1620. The substrate 1610 can be a semiconductor substrate, or any substrates having a layer of semiconductor layer. For example, the substrate can be a single crystal silicon substrate. The substrate can be a silicon-germanium substrate, or can have a silicon germanium layer disposed on top. The gate conductor can include doped polysilicon. The top surfaces of the gate electrode 1620 and the source and drain regions 1640A and 1640B can be exposed. FIG. 16A shows an exemplary metal-oxide-semiconductor field effect transistor (MOSFET) structure 1600, but the invention is not so limited, and can include any transistor structure, such as bipolar transistors, fin transistors or double gate transistors. In addition, the present process flow describes a silicidation process for gate electrode 1620 and on source and drain regions 1640A and 1640B, but the invention is not so limited, and can include silicidation for any combination, for example, for only for the gate electrode 1620, or only for the source or drain regions 1640A or 1640B.

In FIG. 16B, a surface preparation can be performed, such as a preclean step with dilute hydrofluoric acid and/or a native oxide removal step for the exposed gate electrode and source/drain regions. One or more layers 1660/1665 can be deposited on the transistor structure, covering the exposed surfaces of the gate electrode and the source and drain regions. The layers 1660/1665 can be deposited using PVD, CVD, or ALD process. The layers 1660/1665 can include materials to form a silicide layer and/or a dopant layer, according to any of the embodiments disclosed in the present specification. For example, the layers 1660/1665 can include a layer having a silicide metal (such as NiPt) and a dopant (such as Te). The layers 1660/1665 can include a first layer 1665 having a silicide metal (such as NiPt) and a second layer 1660 having a dopant (such as Te).

In FIG. 16C, the substrate, together with the transistor structure 1600 and the layers 1660/1665 can be annealed. The annealing process can include a non-reactive (such as nitrogen or argon) or a reactive ambient (such as H₂S, H₂Se, or H₂Te) to form a silicide layer 1664 and a dopant layer 1662. The annealing process can include a high temperature ambient between 300-600 C for 30-60 seconds. In FIG. 16D, the substrate surface can be cleaned.

In some embodiments, process systems for forming a silicide layer and a dopant layer to improve contract resistance for a semiconductor substrate is disclosed. The process systems can provide in-situ processing between the steps, permitting control of the ambient to prevent contamination.

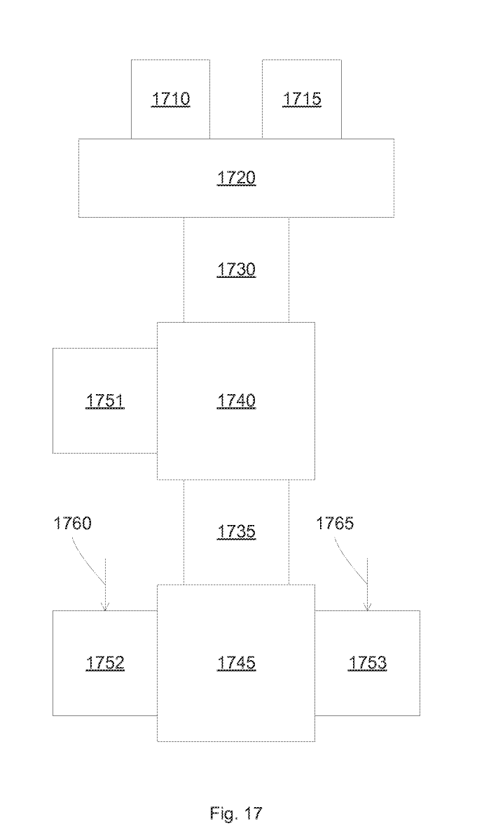

FIG. 17 illustrates an example of a process system according to some embodiments. A front loader 1720 can interface with load locks 1710 and 1715, accepting substrates to bring to a transfer module 1730. The substrate can be transferred to a robot chamber 1740, and can be cleaned in a cleaning module 1751. After cleaning, the substrate can returned to the robot chamber 1740, and can be transferred to the transfer module 1735. The substrate can be transferred to a robot chamber 1745, and then to a deposition module 1752. The deposition module can include a sputter deposition chamber, a chemical vapor deposition chamber, or an atomic layer deposition chamber, with reactive gases 1760. After the layer is deposited, the substrate can returned to the robot chamber 1745, and can be transferred to the anneal module 1753. The anneal module can include a rapid thermal anneal chamber, or a laser anneal chamber. Reactive gases 1765 can be provided to the anneal module 1753. The modules of the process system can be maintained in a vacuum environment, and thus the process between cleaning, to deposition, to annealing, can be performed in-situ, without exposing to the outside ambient.

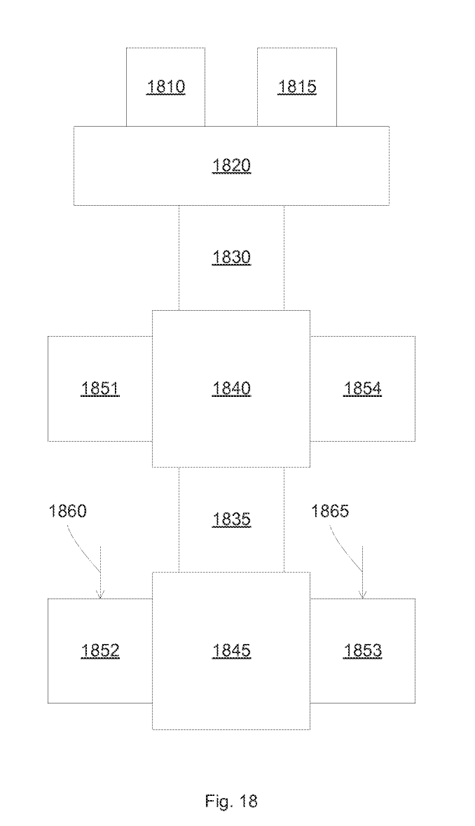

FIG. 18 illustrates an example of a process system according to some embodiments. A front loader 1820 can interface with load locks 1810 and 1815, accepting substrates to bring to a transfer module 1830. The substrate can be transferred to a robot chamber 1840, and can be cleaned in a cleaning module 1851. After cleaning, the substrate can returned to the robot chamber 1840, and can be transferred to the transfer module 1835. The substrate can be transferred to a robot chamber 1845, and then to a first deposition module 1852 to deposit a first layer. The deposition module 1852 can include a sputter deposition chamber, a chemical vapor deposition chamber, or an atomic layer deposition chamber, with reactive gases 1860. After the first layer is deposited, the substrate can returned to the robot chamber 1845, and can be transferred to a second deposition module 1853 to deposit a second layer on the first layer. The deposition module 1853 can include a sputter deposition chamber, a chemical vapor deposition chamber, or an atomic layer deposition chamber, with reactive gases 1865. After the second layer is deposited, the substrate can returned to the robot chamber 1845, and can be transferred to an anneal module 1854. The anneal module can include a rapid thermal anneal chamber, or a laser anneal chamber. The modules of the process system can be maintained in a vacuum environment, and thus the process between cleaning, to deposition, to annealing, can be performed in-situ, without exposing to the outside ambient. In addition, any process sequence can be performed, for example, the second layer can be deposited from deposition module 1853 before depositing the first layer from deposition module 1852.

Although the foregoing examples have been described in some detail for purposes of clarity of understanding, the invention is not limited to the details provided. There are many alternative ways of implementing the invention. The disclosed examples are illustrative and not restrictive.

1. A method for forming a semiconductor device, comprising providing a substrate;
depositing a layer on the substrate using sputtering from one or more targets, wherein the targets comprise
at least one of titanium, cobalt, or platinum, and
at least one of sulfur, selenium, or tellurium;
annealing the substrate.

2. A method as in claim 1 wherein the substrate comprises at least one of silicon, germanium, silicon germanium, or silicon carbide.

3. A method as in claim 1 wherein the targets comprise one single target, wherein the single target comprises between 2 and 10 at % of the at least one of sulfur, selenium, or tellurium.

4. A method as in claim 1 wherein the targets comprise two targets, wherein one target comprises the at least one of titanium, cobalt, or platinum, or another target comprises the at least one of sulfur, selenium, or tellurium.

5. A method as in claim 1 wherein an annealing temperature is between 300 and 600° C.

6. A method as in claim 1 wherein an annealing time is between 30 and 60 seconds.

7. A method as in claim 1 wherein a thickness of the layer is between 2 and 100 nm.

8. A method as in claim 1 further comprising
cleaning the substrate before depositing the layer.

9. A method as in claim 1 further comprising
in-situ cleaning the substrate before depositing the layer.

10. A method for forming a semiconductor device, comprising
providing a substrate;
depositing a layer on the substrate using sputtering from one or more targets in a reactive ambient,
wherein the targets comprise at least one of titanium, cobalt, or platinum,
wherein the reactive ambient comprises one of H₂S, H₂Se, or H₂Te; and
annealing the substrate.

11. A method as in claim 10 wherein the reactive ambient is configured to provide the layer with between 2 and 10 at % of sulfur, selenium, or tellurium.

12. A method as in claim 10 wherein an annealing temperature is between 300 and 600° C. and the annealing time is between 30 and 60 seconds.

13. A method as in claim 10 wherein a thickness of the layer is between 2 and 100 nm.

14. A method as in claim 10 further comprising
cleaning the substrate before depositing the layer.

15. A method as in claim 10 further comprising
in-situ cleaning the substrate before depositing the layer.

16. A method for forming a semiconductor device, comprising
providing a substrate;
sequentially exposing the substrate to a first precursor and a second precursor to deposit a layer on the substrate,
wherein the first precursor comprises at least one of titanium, cobalt, or platinum,
wherein the second precursor comprises one of H₂Se, or H₂Te;
annealing the substrate.

17. A method as in claim 16 wherein the second precursor is configured to provide the layer with between 2 and 10 at % of selenium, or tellurium.

18. A method as in claim 16 wherein an annealing temperature is between 300 and 600° C. and an annealing time is between 30 and 60 seconds.

19. A method as in claim 16 wherein a thickness of the layer is between 2 and 100 nm.

20. A method as in claim 16 further comprising in-situ cleaning the substrate before depositing the layer.
